(19) United States
(12) Patent Application Publication
(10) Pub. No.: US 2013/0316480 A1
(43) Pub. Date: Nov. 28, 2013

(54) Method for Manufacturing Liquid Crystal Display Device

(71) Applicants: Jie Chen, Shenzhen (CN); Chunliang Lee, Shenzhen (CN)

(72) Inventors: Jie Chen, Shenzhen (CN); Chunliang Lee, Shenzhen (CN)

(73) Assignee: Shenzhen China Star Optoelectronics Technology Co. LTD., Shenzhen City, Guangdong (CN)

(21) Appl. No.: 13/575,293

(22) PCT Filed: May 30, 2012
(86) PCT No.: PCT/CN12/76307

§ 371 Date: Jul. 25, 2012

(30) Foreign Application Priority Data
May 22, 2012 (CN) 201210160528.6

(51) Int. Cl. H01L 33/08

(52) U.S. Cl. 438/30; 257/E33.053

(57) ABSTRACT

The present invention provides a method for manufacturing liquid crystal display device, which includes (1) providing a substrate and (2) forming a black matrix on a surface of the substrate and at the same time forming support structures, wherein the support structures are arranged to correspond to the site where an enclosing frame is to be set. The method for manufacturing liquid crystal display device of the present invention forms, simultaneously with a process of forming black matrix, support structures to support box thickness so that the conventional process of adding fibers in sealant to support the box thickness used in the known techniques is replaced. The manufacture process is simplified, while labor deployment is reduced and manufacture cost is lowered down.

### BACKGROUND OF THE INVENTION

1. Field of the Invention

The present invention relates to the field of liquid crystal displaying, and in particular to a method for manufacturing a liquid crystal display device.

2. The Related Arts

Liquid crystal display (LCD) has a variety of advantages, such as thin device body, low power consumption, and being free of radiation, and is thus widely used. Most of the LCDs that are currently available in the market are backlighting LCDs, which comprise a liquid crystal display panel and a backlight module. The working principle of the liquid crystal display panel is that liquid crystal polymer molecules interposed between two parallel glass substrates and a plurality of vertical and horizontal fine electrical wires is arranged between the two glass substrates, whereby the liquid crystal molecules are controlled to change direction by application of electricity in order to refract light emitting from the backlight module for generating images.

As shown in FIG. 1, a liquid crystal display device is generally composed of an upper structure 100 of color filter (CF), a low substrate 200 of thin film transistor (TFT), and liquid crystal (LC) 300 and sealant 400 interposed between the upper substrate 100 and the lower substrate 200. A general manufacturing process comprises a front stage of array process (including thin film, yellow light, etching, and film stripping), an intermediate stage of cell process (including bonding TFT substrate and the CF substrate), and a rear stage of assembling process (including mounting drive ICs and printed circuit board). The front stage of array process generally makes the TFT substrate for controlling the movement of liquid crystal molecules. The intermediate stage of cell process generally introduces the liquid crystal between the TFT substrate and the CF substrate. The rear stage of assembling process generally mounts the drive ICs and combining the printed circuit board to effect driving the liquid crystal molecules to rotate for displaying images.

The process of introducing the liquid crystal 300 between the upper substrate 100 and the lower substrate 200 is a process generally referred to as one drop filling (ODF), which generally comprises several steps of coating the sealant 400, filling the liquid crystal 300, vacuum assembling, and high temperature curing. In the step of coating the sealant 400, it is often that fibers 500 are added to the sealant 400 to provide an effect of supporting box thickness. However, adding fibers 500 increases the manufacturing time and labor required, making it detrimental to controlling cost.

### SUMMARY OF THE INVENTION

An object of the present invention is to provide a method for manufacturing liquid crystal display device, which comprises forming supports for supporting box thickness at the same time when a process of forming black matrix is carried out so as to reduce labor deployment and lower down manufacture cost.

To achieve the object, the present invention provides a method for manufacturing liquid crystal display device, which comprises the following steps:

Step 1: providing a substrate; and

Step 2: forming a black matrix on a surface of the substrate and at the same time forming support structures, wherein the support structures are arranged to correspond to the site where an enclosing frame is to be set.

The black matrix and the support structures are formed through operations of masking, printing, or spray coating.

The support structures are of a regular or irregular shape.

The support structures are of a pillar structure.

The support structures are located inside or outside the enclosing frame.

The support structures are located in the enclosing frame.

A portion of the support structures is located in the enclosing frame and a remaining portion is located inside or outside the enclosing frame.

The support structures are arranged in a spaced manner or in a continuous manner on the substrate.

The substrate is a glass substrate.

The method further comprises the following steps:

Step 3: sequentially forming R, G, B on the surface of the substrate;

Step 4: coating sealant on the site of the surface of the substrates where the enclosing frame is to be set to form the enclosing frame;

Step 5: forming spacers on the surface of the substrate so as to form the CF substrate;

Step 6: dropping liquid crystal inside the enclosing frame;

Step 7: providing a TFT substrate;

Step 8: bonding the TFT substrate and the CF substrate together in such a way that the TFT substrate and the CF substrate are supported by the support structures arranged therebetween in order to enclose the liquid crystal between the TFT substrate and the CF substrate; and

Step 9: subjecting the bonded TFT substrate and the CF substrate to curing at a high temperature in order to solidify the enclosing frame.

The efficacy of the present invention is that the present invention provides a method for manufacturing liquid crystal display device, which forms, simultaneously with a process of forming a black matrix, support structures to support box thickness whereby the process of adding fibers in the sealant to support the box thickness used in the known techniques is replaced. The manufacture process is simplified, while labor deployment is reduced and manufacture cost is lowered down.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, will be apparent from the following detailed description of an embodiment of the present invention, with reference to the attached drawings. In the drawings:

FIG. 1 is a schematic view showing the structure of a conventional liquid crystal display device;

FIG. 2 is a flow chart illustrating a method for manufacturing liquid crystal display device according to the present invention;

FIG. 3 is a schematic view showing the structure of a first embodiment of liquid crystal display device manufactured with the method for manufacturing liquid crystal display device according to the present invention;

FIG. 4 is a perspective view showing a color filter (CF) substrate of FIG. 3;

FIG. 5 is a schematic view showing the structure of a second embodiment of liquid crystal display device manufactured with the method for manufacturing liquid crystal display device according to the present invention;

FIG. 6 is a schematic view showing the structure of a third embodiment of liquid crystal display device manufactured with the method for manufacturing liquid crystal display device according to the present invention;

FIG. 7 is a schematic view showing the structure of a fourth embodiment of liquid crystal display device manufactured with the method for manufacturing liquid crystal display device according to the present invention; and

FIG. 8 is a schematic view showing the structure of a fifth embodiment of liquid crystal display device manufactured with the method for manufacturing liquid crystal display device according to the present invention.

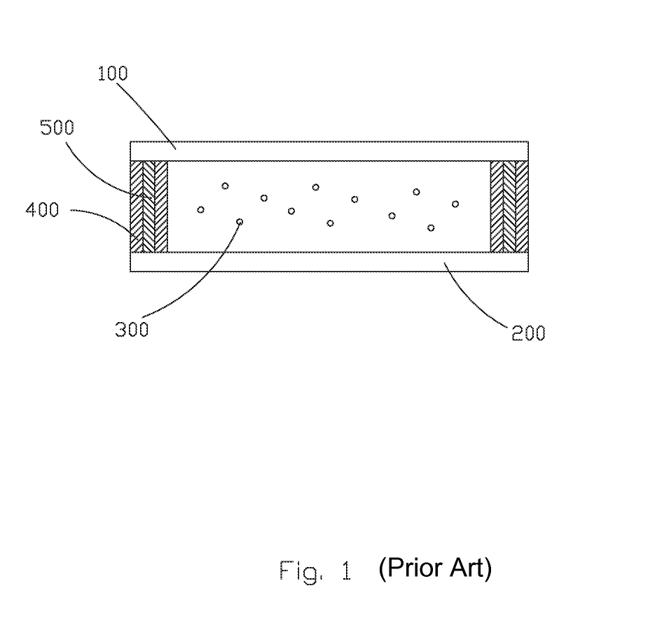

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

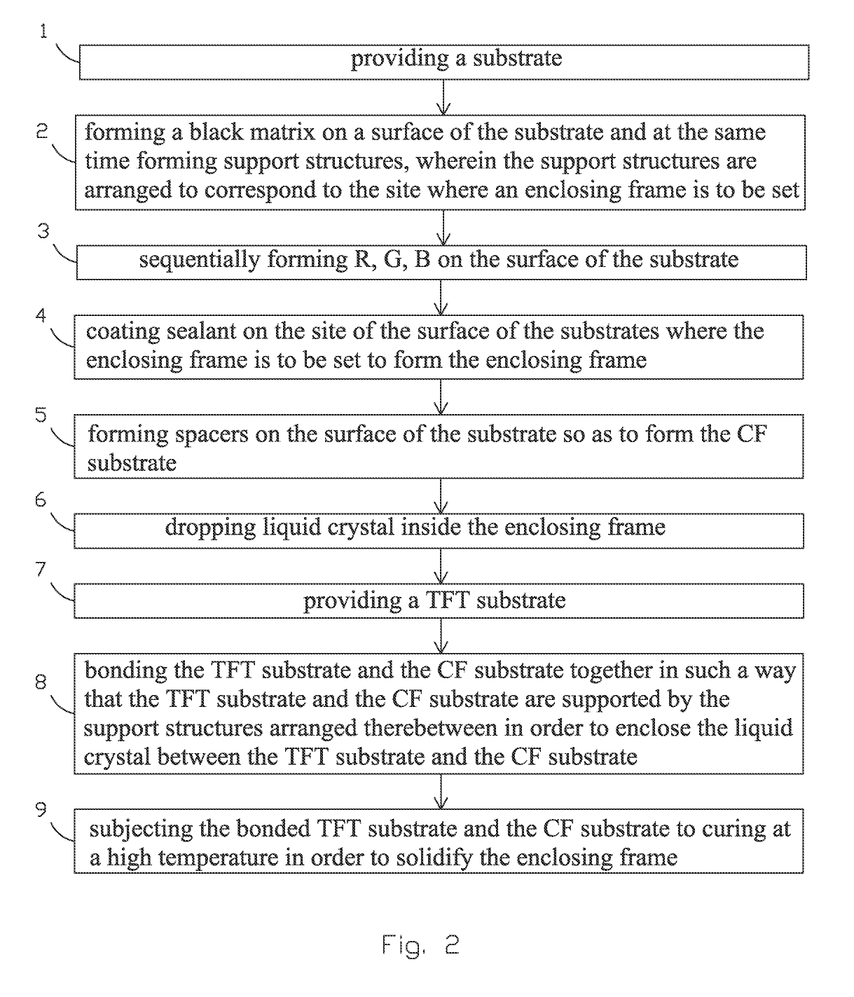

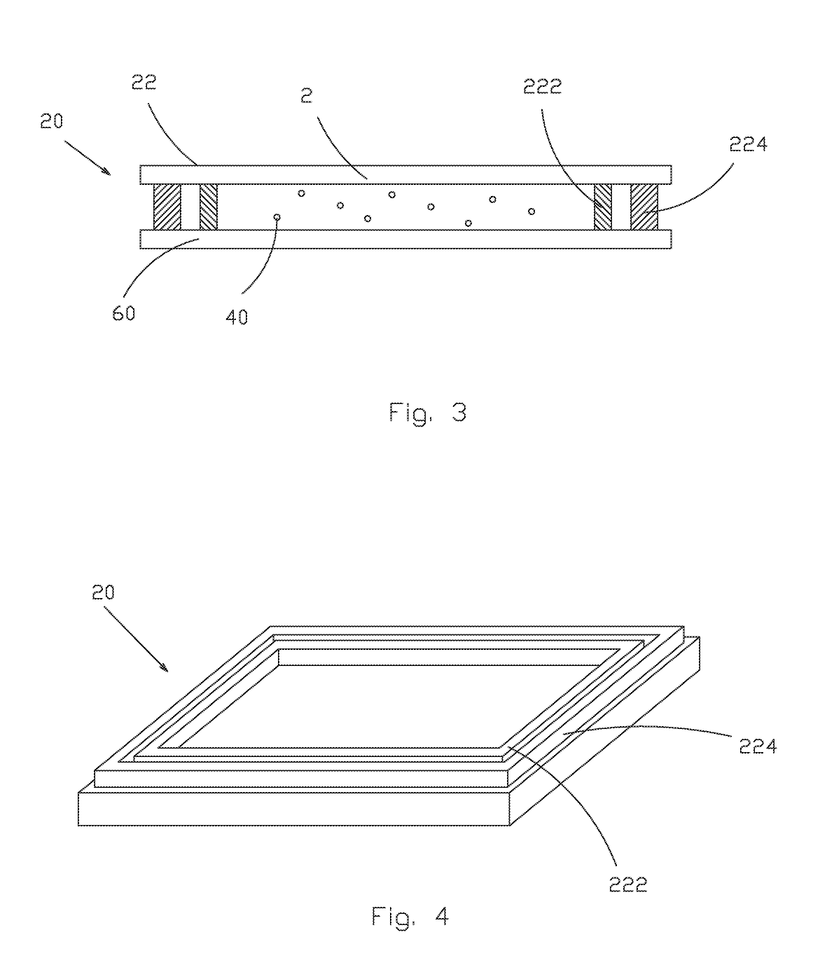

Referring to FIG. 2, with additional reference to FIGS. 3 and 4, the present invention provides a method for manufacturing liquid crystal display device, which comprises the following steps:

Step 1: providing a substrate 2. In the instant embodiment, the substrate 2 is a glass substrate.

Step 2: forming a black matrix (not shown) on a surface 22 of the substrate 2 and at the same time forming support structures 222. The support structures 222 are arranged to correspond to the site where an enclosing frame is to be set. The support structures 222 are arranged on the substrate 2 in a spaced manner. Preferably, the support structures 222 are arranged on the substrate 2 in a uniformly spaced manner. The support structures 222 can be arranged in a continuous manner so as to be continuously set on the substrate 2.

The black matrix is arranged in the form of a polygon, preferably a rectangle. The black matrix and the support structures 222 are formed together on the substrate 2 through operations including masking operation, printing, or spray coating operation.

The support structures 222 can be of a regular or irregular shape. Preferably, the support structures 222 are of a pillar structure, of which the specific shape can be determined according to the requirement of an actual manufacturing process to achieve the same technical effect of the present invention.

Step 3: sequentially forming R, G, B on the surface 22 of the substrate 2.

The R, G, B are formed on the substrates 2 through operations including masking operation, printing, or spray coating operation.

Step 4: coating sealant on the site of the surface 22 of the substrate 2 where the enclosing frame is to be set to form the enclosing frame 224.

The support structures 222 are arranged to correspond to the site where the enclosing frame is to be set and can be located inside or outside the enclosing frame 224 or completely located on the enclosing frame 224 or partially located on the enclosing frame 24. As shown in FIGS. 3 and 4, as an optional embodiment of the present invention, in the instant embodiment, the support structures 222 are located inside the enclosing frame 224.

Step 5: forming spacers (not shown) on the surface 22 of the substrate 2 and at the same time forming supports 222 so as to form a CF (color filter) substrate 20.

Step 6: dropping liquid crystal 40 inside the enclosing frame 224.

Step 7: providing a TFT substrate 60.

The TFT substrate 60 is manufactured through the operations of thin film, yellow light, etching, and film stripping and the specific operations used can be any of the known operations.

Step 8: bonding the TFT substrate 60 and the CF substrate 20 together in such a way that the TFT substrate 60 and the CF substrate 20 are supported by the support structures 222 arranged therebetween in order to enclose the liquid crystal 40 between the TFT substrate 60 and the CF substrate 20 thereby achieving supporting of box thickness between the TFT substrate 60 and the CF substrate 20 by the support structures 222. This simplifies the manufacture process and reduces the manufacture cost.

Step 9: subjecting the bonded TFT substrate 60 and the CF substrate 20 to curing at a high temperature in order to solidify the enclosing frame 224.

Referring to FIG. 5, a schematic view showing the structure of a second embodiment of liquid crystal display device manufactured with the method for manufacturing liquid crystal display device according to the present invention is given. In the instant embodiment, the support structures 222 are located outside the enclosing frame 224.

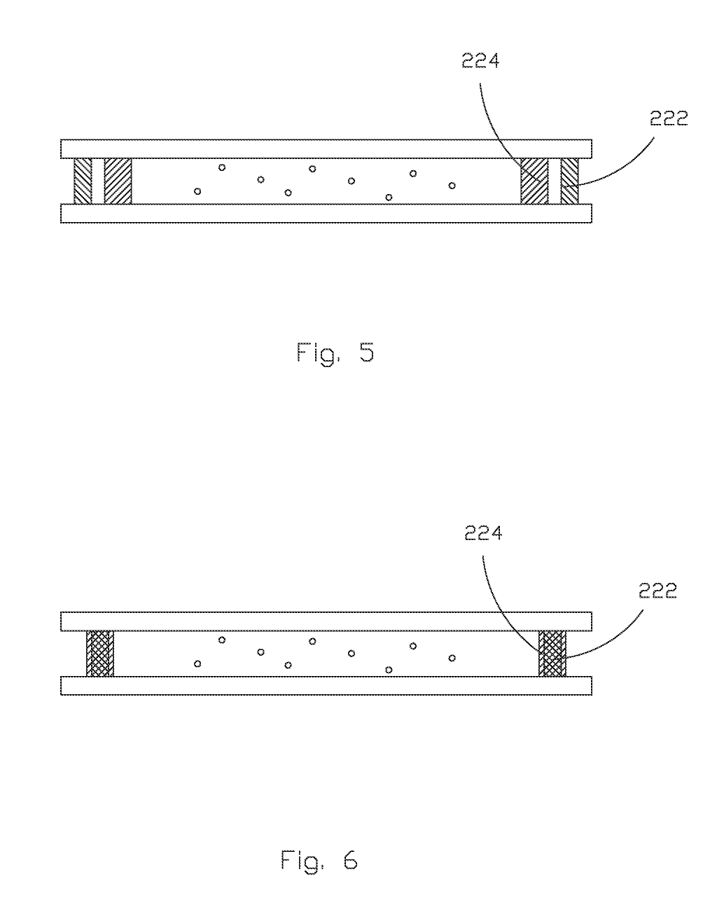

Referring to FIG. 6, a schematic view showing the structure of a third embodiment of liquid crystal display device manufactured with the method for manufacturing liquid crystal display device according to the present invention is given. In the instant embodiment, the support structures 222 are located in the enclosing frame 224.

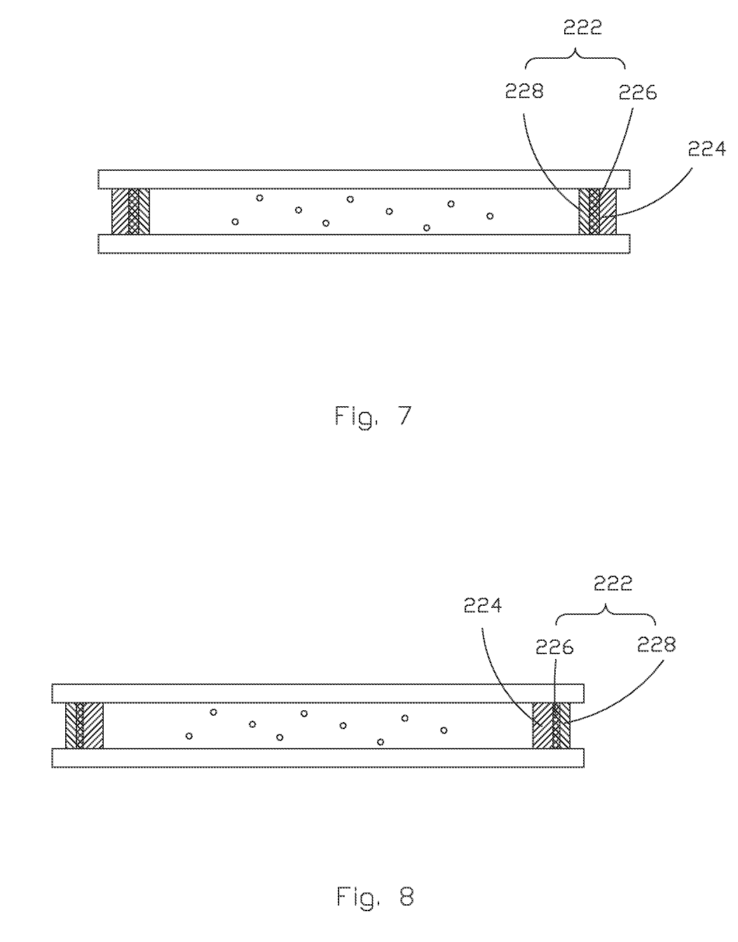

Referring to FIG. 7, a schematic view showing the structure of a fourth embodiment of liquid crystal display device manufactured with the method for manufacturing liquid crystal display device according to the present invention is given. In the instant embodiment, a portion 226 of the support structures 222 is located on the enclosing frame 224, while a remaining portion 228 is located inside the enclosing frame 224.

Referring to FIG. 8, a schematic view showing the structure of a fifth embodiment of liquid crystal display device manufactured with the method for manufacturing liquid crystal display device according to the present invention is given. In the instant embodiment, a portion 226 of the support structures 222 is located on the enclosing frame 224, while a remaining portion 228 is located outside the enclosing frame 224.

In summary, the present invention provides a method for manufacturing liquid crystal display device, which forms, simultaneously with a process of forming a black matrix, support structures to support box thickness whereby the process of adding fibers in the sealant to support the box thickness used in the known techniques is replaced. The manufacture process is simplified, while labor deployment is reduced and manufacture cost is lowered down.

Based on the description given above, those having ordinary skills of the art may easily contemplate various changes and modifications of the technical solution and technical ideas of the present invention and all these changes and modifications are considered within the protection scope of right for the present invention.

1. A method for manufacturing a liquid crystal display device, comprising the following steps:
(1) providing a substrate; and
(2) forming a black matrix on a surface of the substrate and at the same time forming support structures so that the support structures constitute, at least partly, the black matrix, wherein the support structures are arranged to correspond to the site where an enclosing frame is to be set;
(3) sequentially forming R, G, B on the surface of the substrate; and
(4) coating sealant on the site of the surface of the substrate where the enclosing frame is to be set to form the enclosing frame, wherein the sealant is coated in such a way that a portion of the support structures is located in the enclosing frame and a remaining portion of the support structures is located outboard an outside surface of the enclosing frame.

2. The method for manufacturing a liquid crystal display device as claimed in claim 1, wherein the black matrix and the support structures are formed through operations of masking, printing, or spray coating.

3. The method for manufacturing a liquid crystal display device as claimed in claim 1, wherein the support structures are of a regular or irregular shape.

4. The method for manufacturing a liquid crystal display device as claimed in claim 3, wherein the support structures are of a pillar structure.

5-7. (canceled)

8. The method for manufacturing a liquid crystal display device as claimed in claim 1, wherein the support structures are arranged in a spaced manner or in a continuous manner on the substrate.

9. The method for manufacturing a liquid crystal display device as claimed in claim 1, wherein the substrate is a glass substrate.

10. The method for manufacturing a liquid crystal display device as claimed in claim 1, further comprising the following steps:
(5) forming spacers on the surface of the substrate so as to form a color filter (CF) substrate;
(6) dropping liquid crystal inside the enclosing frame;
(7) providing a thin film transistor (TFT) substrate;
(8) bonding the TFT substrate and the CF substrate together in such a way that the TFT substrate and the CF substrate are supported by the support structures arranged therebetween in order to enclose the liquid crystal between the TFT substrate and the CF substrate; and
(9) subjecting the bonded TFT substrate and the CF substrate to curing at a high temperature in order to solidify the enclosing frame.

11. A method for manufacturing a liquid crystal display device, comprising the following steps:
(1) providing a substrate;
(2) forming a black matrix on a surface of the substrate and at the same time forming support structures so that the support structures constitute, at least partly, the black matrix, wherein the support structures are arranged to correspond to the site where an enclosing frame is to be set;
(3) sequentially forming R, G, B on the surface of the substrate;
(4) coating sealant on the site of the surface of the substrates where the enclosing frame is to be set to form the enclosing frame, wherein the sealant is coated in such a way that a portion of the support structures is located in the enclosing frame and a remaining portion of the support structures is located outboard an outside surface of the enclosing frame;
(5) forming spacers on the surface of the substrate so as to form a color filter (CF) substrate;
(6) dropping liquid crystal inside the enclosing frame;
(7) providing a thin film transistor (TFT) substrate;
(8) bonding the TFT substrate and the CF substrate together in such a way that the TFT substrate and the CF substrate are supported by the support structures arranged therebetween in order to enclose the liquid crystal between the TFT substrate and the CF substrate; and
(9) subjecting the bonded TFT substrate and the CF substrate to curing at a high temperature in order to solidify the enclosing frame;
wherein the black matrix and the support structures are formed through masking operation;
wherein the support structures are of a regular shape;
wherein the support structures are of a pillar structure; and
wherein the substrate is a glass substrate.
